(19) United States
(12) Patent Application Publication
(10) Pub. No.: US 2012/0009702 A1
(43) Pub. Date: Jan. 12, 2012

(54) METHOD FOR MANUFACTURING ORGANIC LIGHT EMITTING DIODE DISPLAY

(75) Inventor: Dai-Han Cho, Yongin-City (KR)

(73) Assignee: SAMSUNG MOBILE DISPLAY CO, LTD., Yongin-City (KR)

(21) Appl. No.: 13/098,095

(22) Filed: Apr. 29, 2011

(30) Foreign Application Priority Data
Jul. 7, 2010 (KR) 10-2010-0065566

(51) Int. Cl. H01L 51/56

(52) U.S. Cl. 438/28; 438/26; 257/E51.018; 257/E51.001

(57) ABSTRACT

A method for manufacturing an organic light emitting diode (OLED) display device, the method including: forming a mother substrate that includes a first glass substrate, a second glass substrate, organic light emitting diodes, and a sealant; etching the first and second glass substrates, to reduce the thicknesses thereof; forming a protective layer on the first glass substrate; and dividing the mother substrate into a plurality the displays, by cutting the first substrate through the protective layer.

### CLAIM OF PRIORITY

This application makes reference to, incorporates the same herein, and claims all benefits accruing under 35 U.S.C. §119 from an application for METHOD FOR MANUFACTURING ORGANIC LIGHT EMITTING DIODE DISPLAY earlier filed in the Korean Intellectual Property Office on 7 Jul. 2010 and there duly assigned Korean Patent Application No. 10-2010-0065566.

### BACKGROUND OF THE INVENTION

1. Field of the Invention

An exemplary embodiment of the present disclosure provides a method for manufacturing an organic light emitting diode (OLED) display device.

2. Description of the Related Art

An organic light emitting diode (OLED) display device is a self-emitting display device that forms an image using OLEDs. In the process for manufacturing the OLED display device, the thickness of the display device is reduced, by etching a glass substrate included therein.

However, during the etching process, fine cracks are formed in the glass substrate. The cracks increase the likelihood that the OLED display may be damaged by external impacts. In addition, in a process for cutting the glass substrate, the glass substrate may be easily broken in an unnecessary direction.

The above information disclosed in this Background section is only for enhancement of understanding of the background of the described technology, and therefore, it may contain information that does constitute prior art.

### SUMMARY OF THE INVENTION

The described technology provides a method for manufacturing an organic light emitting diode (OLED) display device having improved impact resistance and stability characteristics.

An exemplary embodiment of the present disclosure provides a method for manufacturing an OLED display device that includes: forming a mother substrate that includes a first glass substrate, a second glass substrate, an OLED, and a sealant; etching the first glass substrate and the second glass substrate; forming a protective layer on at least one surface of the first glass substrate and the second glass substrate; and dividing the mother substrate into a plurality of unit cells, by cutting the surface on which the protective layer is formed.

According to various embodiments, the protective layer may have a thickness in the range of about 10 μm to 25 μm.

According to various embodiments, the haze of the protective layer may be less than about 1%.

According to various embodiments, the adherence between the protective layer and the corresponding substrate may be about 600 gf/25 mm or more.

According to various embodiments, the protective layer may be made of a thermosetting resin.

According to various embodiments, the first glass substrate and the second glass substrate may be arranged opposite to each other, and the OLEDs may be formed on either substrate.

According to various embodiments, the protective layer and the OLED may be formed on the same glass substrate.

According to various embodiments, the sealant may be formed along the edges of the OLED.

According to various embodiments, the cutting may be performed using a physical cutting method.

According to various embodiments, an OLED display can be manufactured that has improved impact resistance and stability characteristics.

Additional aspects and/or advantages of the present disclosure will be set forth in part in the description which follows and, in part, will be obvious from the description, or may be learned by practice of the present disclosure.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a partial cross-sectional view of an organic light emitting diode (OLED) display device that is manufactured by an exemplary method of the present disclosure;

FIG. 2 is a flowchart that illustrating a manufacturing method of an OLED display device according to an exemplary embodiment; and

FIGS. 3 to 5 are partial cross-sectional views that sequentially illustrate the manufacturing method of FIG. 2.

### DETAILED DESCRIPTION OF THE INVENTION

Hereinafter, the present invention will be described more fully hereinafter with reference to the accompanying drawings, in which exemplary embodiments of the invention are shown. As those skilled in the art would realize, the described exemplary embodiments may be modified in various different ways, all without departing from the spirit or scope of the present invention. Like reference numerals designate like elements throughout the specification.

In addition, the size and thickness components shown in the drawings are arbitrarily is shown for understanding and ease of description, but the present invention is not limited thereto. Herein, when a first element is referred to as being formed or disposed “on” a second element, the first element can be disposed directly on the second element, or one or more other elements may be disposed therebetween. When a first element is referred to as being formed or disposed “directly on” a second element, no other elements are disposed therebetween. In addition, when a first element is described as being “connected to” a second element, the first element may be directly connected to the second element, or may be indirectly connected to the second element, via one or more intervening elements.

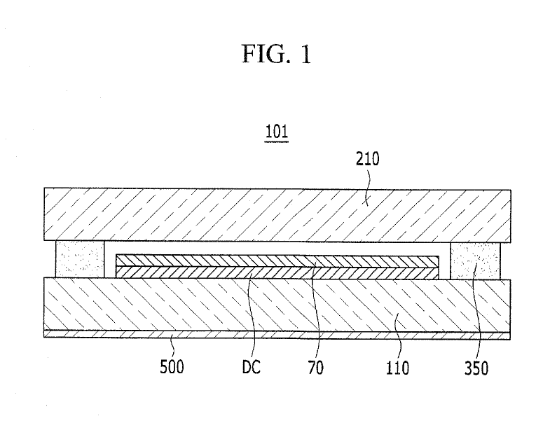

Referring to FIG. 1, an organic light emitting diode (OLED) display device 101 is illustrated, which is manufactured by a method of the present disclosure. As shown in FIG. 1, the display device 101 includes a first glass substrate 110, a second glass substrate 210, an OLED 70, a driving circuit DC, a sealant 350, and a protective layer 500.

The driving circuit DC includes a thin film transistor, and drives the OLED 70. That is, the OLED 70 emits light according to the driving signal that is transferred from the driving circuit portion DC and displays an image. The detailed structures of the driving circuit portion DC and OLED 70 may have various structures that are known to those who are skilled in the art. The OLED 70 may be an array of OLEDs.

The first glass substrate 110 and the second glass substrate 210 are arranged opposite to each other. The OLED 70 and driving circuit DC are formed on the first glass substrate 110. However, the OLED 70 and driving circuit DC may alternatively be formed on the second glass substrate 210.

The sealant 350 is formed between the first glass substrate 110 and the second glass substrate 210, around the OLED 70. The sealant 350 seals the OLED 70 within the substrates 111, 210.

The protective layer 500 is formed on the outer surface of the first glass substrate 110. In the alternative, the protective layer 500 may alternatively be formed on the outer surface of second glass substrate 210. In addition, while the protective layer 500 and the OLED 70 are shown in FIG. 1 as being formed on the same substrate 110, the present disclosure is not limited thereto. In particular, the OLED 70 and protective layer 500 may be formed on different ones of the substrates 110, 210.

Herein, the protective layer 500 will be described with respect to the first glass substrate 110, for ease of description. The protective layer 500 compensates for fine cracks that are formed in the surface of the first glass substrate 110 and protects the first glass substrate 110 from external impacts.

The protective layer 500 may be made of a thermosetting resin. The protective layer 500 may be formed by coating the thermosetting resin on the surface of the first glass substrate 110. However, an exemplary embodiment is not limited thereto. The protective layer 500 may be separately manufactured and then attached to the surface of the first glass substrate 110.

The protective layer 500 generally has a thickness in the range of about 10 μm to 25 μm. If the protective layer 500 has a thickness that is less than about 10 μm, the first glass substrate 110 may be insufficiently protected. On the other hand, if the protective layer 500 has a thickness that is more than about 25 μm, the thickness of the display 101 may be increased unnecessarily.

The protective layer 500 generally has the haze of about 1% or less. If the protective layer 500 has the haze that is more than about 1%, the transparency of the display device 101 may be unnecessarily reduced.

The protective layer 500 is attached to the surface of the first glass substrate 110 with the adherence of about 600 gf/25 mm or more. In the case of when the adherence between the protective layer 500 and the first glass substrate 110 is less than about 600 gf/25 mm, the protective layer 500 may be easily separated from the first glass substrate 110.

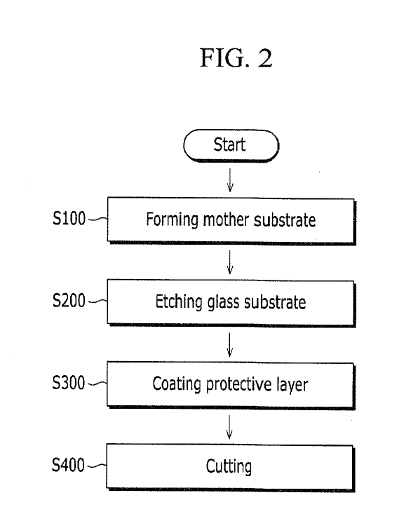

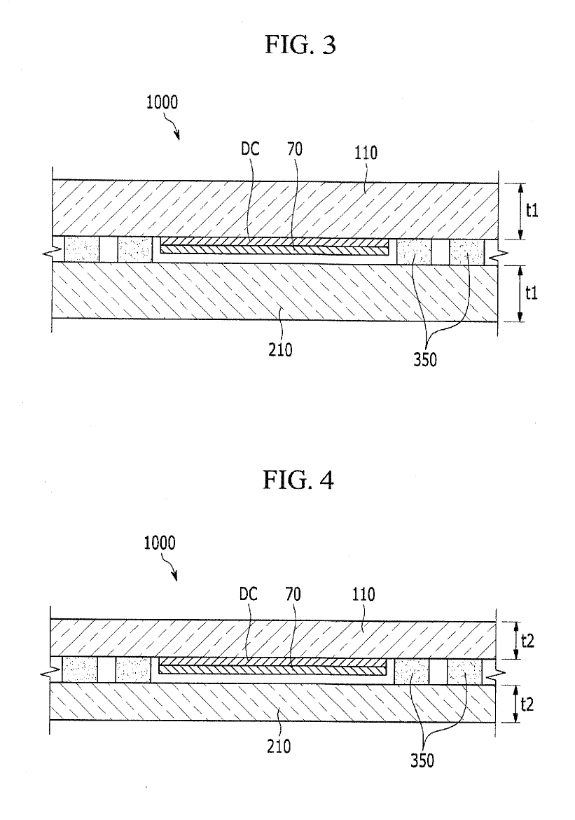

FIGS. 2 to 5, illustrate a method of manufacturing the display device 101, according to an exemplary embodiment of the present disclosure. Referring to FIG. 2 and FIG. 3, a mother substrate 1000 is formed/provided (S100). The mother substrate 1000 includes the first glass substrate 110, second glass substrate 210, OLEDs 70, driving circuit DC, sealant 350, and protective layer 500. The sealant 350 is disposed around arrays of the OLEDs 70. As such, the mother substrate 1000 may be divided into a plurality of unit cells that each correspond to one of the displays 101 of FIG. 1, as discussed below.

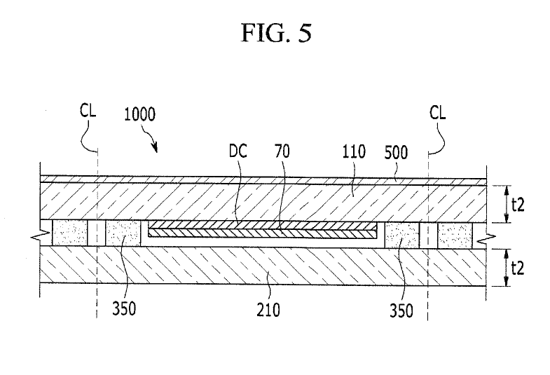

Next, as shown in FIGS. 2 and 4, the first glass substrate 110 and the second glass substrate 210 are etched, to reduce the thicknesses thereof (S200). The thickness t2 of the etched glass substrates 110 and 210 is less than the thickness t1 of the glass substrates 110 and 210 before the etching. Here, various known etching methods may be used.

Next, as shown in FIG. 2 and FIG. 5, the protective layer 500 is formed on the outer surface of the first glass substrate 110 (S300). In the alternative, the protective layer 500 may be formed on the second glass substrate 210.

The protective layer 500, as described above, is made of thermosetting resin, and is formed to a thickness ranging from about 10 μm to 25 μm. The protective layer 500 has a haze of 1% or less. In addition, the protective layer 500 and the first glass substrate 110 are attached with an adherence of 600 gf/25 mm or more.

The protective layer 500 compensates for fine cracks or grooves formed in the first glass substrate 110, during the etching process. That is, the protective layer 500 fills the fine cracks, to improve the damage resistance of the display 101.

Next, the mother substrate 1000 is divided into the plurality of unit cells, by cutting the mother substrate 1000 through the protective layer 500, along cutting lines CL (S400). In this case, the cutting is performed using a physical cutting method. In addition, the protective layer 500 prevents the first glass substrate 110 from being damaged during the cutting process. Accordingly, a plurality of the displays 101 are formed from the mother substrate 1000.

As described above, the protective layer 500 compensates for the fine cracks that are generated during the etching of the first glass substrate 110, and protects the first glass substrate 110 during the cutting process. Accordingly, an OLED display device can be manufactured, so as to have improved impact resistance and stability.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing an organic light emitting diode (OLED) display device, comprising:
forming a mother substrate that includes a first glass substrate, a second glass substrate, an OLED, and a sealant;
etching the first and second glass substrates, to reduce the thicknesses thereof;
forming a protective layer on the first glass substrate; and
cutting the first glass substrate through the protective layer, to separate the OLED display device from the mother substrate.

2. The method of claim 1, wherein the protective layer has a thickness in the range of about 10 μm to 25 μm.

3. The method of claim 1, wherein the haze of the protective layer is less than about 1%.

4. The method of claim 1, wherein the adherence between the protective layer and the first glass substrate is at least about 600 gf/25 mm.

5. The method of claim 1, wherein the protective layer comprises a thermosetting resin.

6. The method of claim 1, wherein:
the first glass substrate and the second glass substrate are arranged opposite to each other; and
the OLED is formed on one of the first and second glass substrates.

7. The method of claim 6, wherein the protective layer and the OLED are formed both formed on the same one of the first and second glass substrates.

8. The method of claim 6, wherein the sealant is formed around the edges of the OLED.

9. The method of claim 6, wherein the cutting is performed using a physical cutting method.

10. A method of manufacturing an organic light emitting diode (OLED) display device, comprising:
forming a mother substrate that includes opposing first and second glass substrates, OLEDs disposed therebetween, and a sealant disposed around the OLEDs;
etching the first and second glass substrates, to reduce the thicknesses thereof;
forming a protective layer on the first glass substrate; and
cutting through the protective layer and first glass substrate, using a physical cutting method, to divide the mother substrate into a plurality the OLED displays.

11. The method of claim 10, wherein the protective layer comprises a thermosetting resin having an adherence to the first glass substrate of least about 600 gf/25 mm, a thickness in the range of about 10 μm to 25 μm, and haze of less than about 1%.
